(19) United States
(12) Patent Application Publication
(10) Pub. No.: US 2024/0411149 A1
(43) Pub. Date: Dec. 12, 2024

(54) Speckle Reduction

(71) Applicant: Envisics Ltd, Milton Keynes (GB)

(72) Inventors: Edward Boardman, Milton Keynes (GB); Timothy Smeeton, Milton Keynes (GB)

(21) Appl. No.: 18/738,029

(22) Filed: Jun. 9, 2024

(30) Foreign Application Priority Data
Jun. 12, 2023 (GB) 2308723.2

(51) Int. Cl. G02B 27/48; G02B 27/01; G02B 27/09; G03H 1/22

(52) U.S. Cl. CPC G02B 27/48; G02B 27/0172; G02B 27/0905; G02B 27/0955; G03H 1/2205; G03H 1/2286; G02B 2027/0174; G03H 2001/2231; G03H 2222/12; G03H 2222/34

(57) ABSTRACT

A holographic projector comprising a display device, a laser diode chip and at least one optic. The display device is arranged to display a hologram of a picture. The laser diode chip comprising a plurality of emitters. Each emitter is arranged to form a respective beamlet. The beamlets are incoherent with each other such that they form different speckle patterns. The at least one optic is arranged to receive the plurality of beamlets and form a continuous beam in which beamlets of the plurality of beamlets at least partially overlap. The holographic projector is arranged to illuminate the hologram with the continuous beam and form a holographic reconstruction of the picture. The speckle patterns of the beamlets reduce noise in the holographic reconstruction through addition of intensity rather than amplitude and phase.

### CROSS-REFERENCE TO RELATED APPLICATIONS

This application claims priority under 35 U.S.C. § 119 to UK Patent Application GB 2308723.2 titled “Speckle Reduction,” filed on Jun. 12, 2023, and currently pending. The entire contents of GB 2308723.2 are incorporated by reference herein for all purposes

### FIELD

The present disclosure relates to a holographic projector comprising a multi-emitter laser. More specifically, the present disclosure relates to a holographic projector comprising a laser diode chip having a plurality of emitters, each emitter being arranged to form a respective beamlet, and an optic arranged to receive the beamlets and form a continuous beam in which the beamlets at least partially overlap. Some embodiments relate to a retina display and/or a head-up display.

### INTRODUCTION

Light scattered from an object contains both amplitude and phase information. This amplitude and phase information can be captured on, for example, a photosensitive plate by well-known interference techniques to form a holographic recording, or “hologram”, comprising interference fringes. The hologram may be reconstructed by illumination with suitable light to form a two-dimensional or three-dimensional holographic reconstruction, or replay image, representative of the original object.

Computer-generated holography may numerically simulate the interference process. A computer-generated hologram may be calculated by a technique based on a mathematical transformation such as a Fresnel or Fourier transform. These types of holograms may be referred to as Fresnel/Fourier transform holograms or simply Fresnel/Fourier holograms. A Fourier hologram may be considered a Fourier domain/plane representation of the object or a frequency domain/plane representation of the object. A computer-generated hologram may also be calculated by coherent ray tracing or a point cloud technique, for example.

A computer-generated hologram may be encoded on a spatial light modulator arranged to modulate the amplitude and/or phase of incident light. Light modulation may be achieved using electrically-addressable liquid crystals, optically-addressable liquid crystals or micro-mirrors, for example.

A spatial light modulator typically comprises a plurality of individually-addressable pixels which may also be referred to as cells or elements. The light modulation scheme may be binary, multilevel or continuous. Alternatively, the device may be continuous (i.e. is not comprised of pixels) and light modulation may therefore be continuous across the device. The spatial light modulator may be reflective meaning that modulated light is output in reflection. The spatial light modulator may equally be transmissive meaning that modulated light is output in transmission.

A holographic projector may be provided using the system described herein. Such projectors have found application in head-up displays, “HUDs”.

A holographic display with 2D pupil expansion produces replicas of the content over the full range of the supported eyebox whenever the light sources are on. This results in low efficiency because only light which enters the eye, the area of which is much smaller than the eyebox, contributes to the luminance of the image.

Therefore, lasers are considered a preferred light source for a pupil expanded holographic display because they combine high coherence, necessary for producing high quality images using holography, with high optical power, which compensates for the inherent lossiness of pupil expansion.

However, the high spatial coherence of laser light results in the well-known phenomenon of laser speckle, which degrades image quality. A common method to reduce the effect of speckle on image quality is to time-average a large number of different speckle patterns within the image retention time of the eye.

### SUMMARY

Aspects of the present disclosure are defined in the appended independent claims.

In an aspect, there is provided a holographic projector comprising a display device arranged to display a hologram of a picture. The holographic projector further comprises a laser diode chip comprising a plurality of emitters, each emitter of the plurality of emitters being arranged to form a respective beamlet. The beamlets are incoherent with each other such that they form different speckle patterns. The holographic projector further comprises an optic arranged to receive the plurality of beamlets and form a continuous beam in which beamlets of the plurality of beamlets at least partially overlap, thereby to smooth/even out the different speckle patterns. The holographic projector is arranged to illuminate the hologram with the continuous beam thereby to form a holographic reconstruction of the picture.

Notably, the respective speckle patterns of the plurality of emitters are incoherent with each other meaning that, when overlapped, they add in intensity rather than amplitude and phase. In some embodiments, the different speckle patterns do not interfere with each other. The inventors have found that this reduces non-uniformities in the image caused by laser speckle. For the avoidance of doubt, a distinction is drawn between configurations in which speckle patterns that are coherent with each other are combined through constructive and destructive interference. The inventors have found that the superposition of speckle patterns that are incoherent with each other is more effective at increasing the perceived quality of a holographic reconstruction, and they have identified a convenient source for these different speckle patterns that can be used to form a compact holographic projector.

Providing multiple emitters on the same laser chip tends to advantageously enable higher power to be efficiently coupled onto the spatial light modulator of the holographic display from a small range of angles. As a result, high resolution in the holographic reconstruction tends to be achieved.

The laser diode chip may comprise a plurality of ridges corresponding to the plurality of emitters.

For a given laser diode chip, each ridge tends to emit light having a wavelength which is substantially the same as that of the other ridges, since the wavelength of emission is determined by the material composition of the emitting layer of an emitter. In contrast, where instead multiple different laser diode chips are used, there is likely to be a wavelength spread due to variations in the doping process during fabrication of the emitting layers of the respective chips. A wavelength spread is detrimental to image quality due to the diffractive mechanism of spatial light modulators, because different wavelengths are diffracted to varying extents, resulting in a blurring of the content of the holographic reconstruction, particularly at field of view edges. Hence, a projector according to this aspect which instead implements a single laser diode chip having multiple emitters tends to advantageously benefit from mitigation of such blurring.

A dimension of an output port of each emitter may be less than 50 micrometres.

The dimension of the output port of each emitter may be less than 20 micrometres.

A distance between adjacent emitters of the plurality of emitters may be less than 500 micrometres.

Such a proximity of adjacent emitters tends to advantageously maintain a high uniformity of illumination of the spatial light modulator, while increasing total optical power.

A distance between adjacent emitters of the plurality of emitters may be less than 200 micrometres.

Such a proximity of adjacent emitters tends to advantageously maintain a particularly high uniformity of illumination of the spatial light modulator, while particularly increasing total optical power.

Reducing the proximity of the emitters to one another maximises the resolution of the resulting picture. A distance between adjacent emitters of the plurality of emitters may be less than 40 microns. This can achieve a resolution of approximately 75 ppd.

The optic may be a collimating lens.

Advantageously, use of a single collimation optic tends to allow for simplification of the projector design compared to conventional projectors which would otherwise require, for example, incorporation of fibre-coupled single emitters, each with a dedicated collimating optic, to give the desired output.

The overlap may comprise at least 50% of a dimension (e.g., a diameter or length of a major axis) of each beamlet. The overlap may comprise at least 75% of a dimension of each beamlet.

The hologram may be arranged to divide or distribute content of the holographic reconstruction of the picture by angle such that different angular ranges of light diffracted by the hologram correspond to different spatial areas or portions or slices of the picture.

In a further aspect, there is provided a retina display comprising the holographic projector according to the above aspect.

In a yet further aspect, there is provided a head-up display comprising the retina display according to the preceding aspects.

In a yet further aspect, there is provided a method of reducing noise (e.g., laser speckle) in a retina display, the method being performable by a holographic projector. The method comprises receiving, by an optic of the holographic projector, a plurality of beamlets, each beamlet of the plurality of beamlets being incoherent with each other such that they form different speckle patterns. The method further comprises forming, by the optic, a continuous beam in which the plurality of beamlets at least partially overlap. The method further comprises illuminating a hologram of a picture with the continuous beam thereby to form a holographic reconstruction of the picture.

The respective speckle patterns of the plurality of emitters tend to superpose and, by virtue of the incoherence of the beamlets, destructively interfere. As a result, the superposed speckle patterns tend to advantageously exhibit reduced amplitude, resulting in an image which has reduced non-uniformity, i.e. less noise, due to laser speckle.

Providing multiple emitters on the same laser chip tends to advantageously enable higher power to be efficiently coupled onto the spatial light modulator of the holographic display from a small range of angles. As a result, high resolution in the holographic reconstruction tends to be achieved.

The method may further comprise, prior to the receiving, by the optic of the holographic projector, the plurality of beamlets, emitting, from a plurality of emitters of a laser diode chip of the holographic projector, the plurality of beamlets.

The emitting, from a plurality of emitters of the laser diode chip, the plurality of beamlets may include emitting, from a plurality of ridges of the laser diode chip, the plurality of beamlets.

For a given laser diode chip, each ridge tends to emit light having a wavelength which is substantially the same as that of the other ridges, since the wavelength of emission is determined by the material composition of the emitting layer of an emitter. In contrast, where instead multiple different laser diode chips are used, there is likely to be a wavelength spread due to variations in the doping process during fabrication of the emitting layers of the respective chips. A wavelength spread is detrimental to image quality due to the diffractive mechanism of spatial light modulators, because different wavelengths are diffracted to varying extents, resulting in a blurring of the content of the holographic reconstruction, particularly at field of view edges. Hence, a projector according to this aspect which instead implements a single laser diode chip having multiple emitters tends to advantageously benefit from mitigation of such blurring.

A dimension of an output port of each emitter may be less than 50 micrometres.

The dimension of the output port of each emitter may be less than 20 micrometres.

A distance between adjacent emitters of the plurality of emitters may be less than 500 micrometres.

Such a proximity of adjacent emitters tends to advantageously maintain a high uniformity of illumination of the spatial light modulator, while increasing total optical power.

A distance between adjacent emitters of the plurality of emitters may be less than 200 micrometres.

Such a proximity of adjacent emitters tends to advantageously maintain a particularly high uniformity of illumination of the spatial light modulator, while particularly increasing total optical power.

The optic may be a collimating lens.

Advantageously, use of a single collimation optic tends to allow for simplification of the projector design compared to conventional projectors which would otherwise require, for example, incorporation of fibre-coupled single emitters, each with a dedicated collimating optic, to give the desired output.

The overlap may comprise at least 50% of a dimension (e.g. diameter or length of a major axis) of each beamlet. The overlap may comprise at least 75% of a dimension of each beamlet.

The method may further comprise dividing or distributing, by the hologram, content of the holographic reconstruction of the picture by angle such that different angular ranges of light diffracted by the hologram correspond to different spatial areas or portions or slices of the picture.

There is also disclosed herein a display system comprising a display device and an illumination device comprising a laser diode chip. The laser diode chip comprises a plurality of emitters. Each emitter of the plurality of emitters is arranged to form a respective beamlet. The beamlets are incoherent with each other such that they form different speckle patterns. The display system further comprises at least one optic arranged to receive the plurality of beamlets and form a continuous beam in which beamlets of the plurality of beamlets at least partially overlap. Because the beamlets are incoherent with each other they combine/add in intensity rather than amplitude and phase. This acts to smooth/even out the different speckle patterns and improve the uniformity of the light pattern illuminating the display device. In some embodiments, this improves the quality of an image formed by the display system.

In the present disclosure, the term “replica” is merely used to reflect that spatially modulated light is divided such that a complex light field is directed along a plurality of different optical paths. The word “replica” is used to refer to each occurrence or instance of the complex light field after a replication event-such as a partial reflection-transmission by a pupil expander. Each replica travels along a different optical path. Some embodiments of the present disclosure relate to propagation of light that is encoded with a hologram, not an image—i.e., light that is spatially modulated with a hologram of an image, not the image itself. It may therefore be said that a plurality of replicas of the hologram are formed. The person skilled in the art of holography will appreciate that the complex light field associated with propagation of light encoded with a hologram will change with propagation distance. Use herein of the term “replica” is independent of propagation distance and so the two branches or paths of light associated with a replication event are still referred to as “replicas” of each other even if the branches are a different length, such that the complex light field has evolved differently along each path. That is, two complex light fields are still considered “replicas” in accordance with this disclosure even if they are associated with different propagation distances-providing they have arisen from the same replication event or series of replication events.

A “diffracted light field” or “diffractive light field” in accordance with this disclosure is a light field formed by diffraction. A diffracted light field may be formed by illuminating a corresponding diffractive pattern. In accordance with this disclosure, an example of a diffractive pattern is a hologram and an example of a diffracted light field is a holographic light field or a light field forming a holographic reconstruction of an image. The holographic light field forms a (holographic) reconstruction of an image on a replay plane. The holographic light field that propagates from the hologram to the replay plane may be said to comprise light encoded with the hologram or light in the hologram domain. A diffracted light field is characterized by a diffraction angle determined by the smallest feature size of the diffractive structure and the wavelength of the light (of the diffracted light field). In accordance with this disclosure, it may also be said that a “diffracted light field” is a light field that forms a reconstruction on a plane spatially separated from the corresponding diffractive structure. An optical system is disclosed herein for propagating a diffracted light field from a diffractive structure to a viewer. The diffracted light field may form an image.

The term “hologram” is used to refer to the recording which contains amplitude information or phase information, or some combination thereof, regarding the object. The term “holographic reconstruction” is used to refer to the optical reconstruction of the object which is formed by illuminating the hologram. The system disclosed herein is described as a “holographic projector” because the holographic reconstruction is a real image and spatially-separated from the hologram. The term “replay field” is used to refer to the 2D area within which the holographic reconstruction is formed and fully focused. If the hologram is displayed on a spatial light modulator comprising pixels, the replay field will be repeated in the form of a plurality diffracted orders wherein each diffracted order is a replica of the zeroth-order replay field. The zeroth-order replay field generally corresponds to the preferred or primary replay field because it is the brightest replay field. Unless explicitly stated otherwise, the term “replay field” should be taken as referring to the zeroth-order replay field. The term “replay plane” is used to refer to the plane in space containing all the replay fields. The terms “image”, “replay image” and “image region” refer to areas of the replay field illuminated by light of the holographic reconstruction. In some embodiments, the “image” may comprise discrete spots which may be referred to as “image spots” or, for convenience only, “image pixels”.

The terms “encoding”, “writing” or “addressing” are used to describe the process of providing the plurality of pixels of a spatial light modulator with a respective plurality of control values which respectively determine the modulation level of each pixel. It may be said that the pixels of the spatial light modulator are configured to “display” a light modulation distribution in response to receiving the plurality of control values. Thus, the spatial light modulator may be said to “display” a hologram and the hologram may be considered an array of light modulation values or levels.

It has been found that a holographic reconstruction of acceptable quality can be formed from a “hologram” containing only phase information related to the Fourier transform of the original object. Such a holographic recording may be referred to as a phase-only hologram. Embodiments relate to a phase-only hologram but the present disclosure is equally applicable to amplitude-only holography, in which a holographic reconstruction of acceptable quality can be formed from a “hologram” containing only amplitude information related to the Fourier transform of the original object.

The present disclosure is also equally applicable to forming a holographic reconstruction using amplitude and phase information related to the Fourier transform of the original object. In some embodiments, this is achieved by complex modulation using a so-called fully complex hologram which contains both amplitude and phase information related to the original object. Such a hologram may be referred to as a fully-complex hologram because the value (grey level) assigned to each pixel of the hologram has an amplitude and phase component. The value (grey level) assigned to each pixel may be represented as a complex number having both amplitude and phase components. In some embodiments, a fully-complex computer-generated hologram is calculated.

Reference may be made to the phase value, phase component, phase information or, simply, phase of pixels of the computer-generated hologram or the spatial light modulator as shorthand for “phase-delay”. That is, any phase value described is, in fact, a number (e.g. in the range 0 to 2π) which represents the amount of phase retardation provided by that pixel. For example, a pixel of the spatial light modulator described as having a phase value of π/2 will retard the phase of received light by π/2 radians. In some embodiments, each pixel of the spatial light modulator is operable in one of a plurality of possible modulation values (e.g. phase delay values). The term “grey level” may be used to refer to the plurality of available modulation levels. For example, the term “grey level” may be used for convenience to refer to the plurality of available phase levels in a phase-only modulator even though different phase levels do not provide different shades of grey. The term “grey level” may also be used for convenience to refer to the plurality of available complex modulation levels in a complex modulator.

The hologram therefore comprises an array of grey levels—that is, an array of light modulation values such as an array of phase-delay values or complex modulation values. The hologram is also considered a diffractive pattern because it is a pattern that causes diffraction when displayed on a spatial light modulator and illuminated with light having a wavelength comparable to, generally less than, the pixel pitch of the spatial light modulator. Reference is made herein to combining the hologram with other diffractive patterns such as diffractive patterns functioning as a lens or grating. For example, a diffractive pattern functioning as a grating may be combined with a hologram to translate the replay field on the replay plane or a diffractive pattern functioning as a lens may be combined with a hologram to focus the holographic reconstruction on a replay plane in the near field.

Although different embodiments and groups of embodiments may be disclosed separately in the detailed description which follows, any feature of any embodiment or group of embodiments may be combined with any other feature or combination of features of any embodiment or group of embodiments. That is, all possible combinations and permutations of features disclosed in the present disclosure are envisaged.

### BRIEF DESCRIPTION OF THE DRAWINGS

Specific embodiments are described herein by way of example only, with reference to the following figures:

FIG. 1 is a schematic illustration depicting a reflective spatial light modulator producing a holographic reconstruction on a screen;

FIG. 2 is a schematic illustration depicting an image for projection comprising eight image areas/components and cross-sections of corresponding hologram channels;

FIG. 3 is a schematic illustration depicting a hologram displayed on an LCOS that directs light into a plurality of discrete areas;

FIG. 4 is a schematic illustration depicting a system including a display device which displays a hologram calculated as outlined in the descriptions of FIGS. 2 and 3;

FIG. 5A is a perspective view depicting an exemplary two-dimensional pupil expander comprising two replicators, each of which comprises a pair of stacked surfaces;

FIG. 5B is a perspective view depicting an exemplary two-dimensional pupil expander comprising two replicators, each in the form of a solid waveguide;

FIG. 6A is a schematic illustration depicting a multi-emitter laser illuminating an optic; and

FIG. 6B is a schematic illustration depicting the multi-emitter laser.

The same reference numbers will be used throughout the drawings and the descriptions thereof to refer to the same or like parts.

### DETAILED DESCRIPTION OF EMBODIMENTS

The present invention is not restricted to the embodiments described in the following but extends to the full scope of the appended claims. That is, the present invention may be embodied in different forms and should not be construed as limited to the described embodiments, which are set out for the purpose of illustration.

Terms of a singular form may include plural forms unless specified otherwise.

A structure described as being formed at an upper portion/lower portion of another structure or on/under the other structure should be construed as including a case where the structures contact each other and, moreover, a case where a third structure is disposed there between.

In describing a time relationship—for example, when the temporal order of events is described as “after”, “subsequent”, “next”, “before” or suchlike—the present disclosure should be taken to include continuous and non-continuous events unless otherwise specified. For example, the description should be taken to include a case which is not continuous unless wording such as “just”, “immediate” or “direct” is used.

Although the terms “first”, “second”, etc. may be used herein to describe various elements, these elements are not to be limited by these terms. These terms are only used to distinguish one element from another. For example, a first element could be termed a second element, and, similarly, a second element could be termed a first element, without departing from the scope of the appended claims.

Features of different embodiments may be partially or overall coupled to or combined with each other, and may be variously inter-operated with each other. Some embodiments may be carried out independently from each other, or may be carried out together in co-dependent relationship.

In the present disclosure, the term “substantially” when applied to a structural units of an apparatus may be interpreted as the technical feature of the structural units being produced within the technical tolerance of the method used to manufacture it.

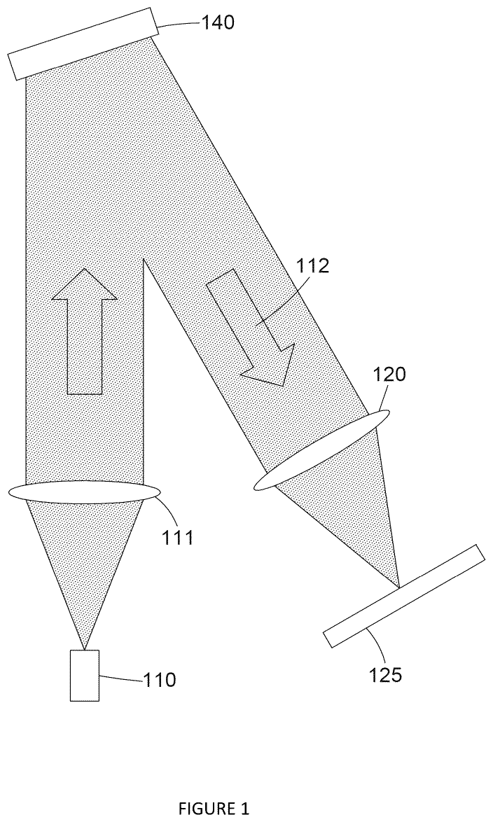

FIG. 1 depicts a reflective spatial light modulator producing a holographic reconstruction on a screen.

FIG. 1 depicts an embodiment in which a computer-generated hologram is encoded on a single spatial light modulator. The computer-generated hologram is a Fourier transform of the object for reconstruction. It may therefore be said that the hologram is a Fourier domain or frequency domain or spectral domain representation of the object. In this embodiment, the spatial light modulator is a reflective liquid crystal on silicon, “LCOS”, device. The hologram is encoded on the spatial light modulator and a holographic reconstruction is formed at a replay field, for example, a light receiving surface such as a screen or diffuser.

A light source 110, for example a laser or laser diode, is disposed to illuminate the spatial light modulator (SLM) 140 via a collimating lens 111. The collimating lens causes a generally planar wavefront of light to be incident to the SLM. In FIG. 1, the direction of the wavefront is off-normal (e.g. two or three degrees away from being truly orthogonal to the plane of the transparent layer). However, in other embodiments, the generally planar wavefront is provided at normal incidence and a beam splitter arrangement is used to separate the input and output optical paths. In the embodiment shown in FIG. 1, the arrangement is such that light from the light source is reflected off a mirrored rear surface of the SLM and interacts with a light-modulating layer to form an exit wavefront 112. The exit wavefront 112 is applied to optics including a Fourier transform lens 120, having its focus at a screen 125. More specifically, the Fourier transform lens 120 receives a beam of modulated light from the SLM 140 and performs a frequency-space transformation to produce a holographic reconstruction at the screen 125.

Notably, in this type of holography, each pixel of the hologram contributes to the whole reconstruction. There is not a one-to-one correlation between specific points (or image pixels) on the replay field and specific light-modulating elements (or hologram pixels). In other words, modulated light exiting the light-modulating layer is distributed across the replay field.

In these embodiments, the position of the holographic reconstruction in space is determined by the dioptric (focusing) power of the Fourier transform lens. In the embodiment shown in FIG. 1, the Fourier transform lens is a physical lens. That is, the Fourier transform lens is an optical Fourier transform lens and the Fourier transform is performed optically. Any lens can act as a Fourier transform lens but the performance of the lens will limit the accuracy of the Fourier transform it performs. The skilled person understands how to use a lens to perform an optical Fourier transform. In some embodiments of the present disclosure, the lens of the viewer's eye performs the hologram to image transformation.

In some embodiments, the computer-generated hologram is a Fourier transform hologram, or simply a Fourier hologram or Fourier-based hologram, in which an image is reconstructed in the far field by utilising the Fourier transforming properties of a positive lens. The Fourier hologram is calculated by Fourier transforming the desired light field in the replay plane back to the lens plane. Computer-generated Fourier holograms may be calculated using Fourier transforms.

Some embodiments described herein relate to Fourier holography and Gerchberg-Saxton type algorithms, by way of example only. The present disclosure is equally applicable to Fresnel holography and Fresnel holograms which may be calculated by a similar appropriate method. In some embodiments, the hologram is a phase or phase-only hologram. However, the present disclosure is also applicable to holograms calculated by other techniques such as those based on point cloud methods.

In some embodiments, the hologram engine is arranged to exclude from the hologram calculation the contribution of light blocked by a limiting aperture of the display system.

UK patent application 2101666.2, filed 5 Feb. 2021 and incorporated herein by reference, discloses a first hologram calculation method in which eye-tracking and ray tracing are used to identify a sub area of the display device for calculation of a point cloud hologram which eliminates ghost images. The sub-area of the display device may be considered to correspond to the aperture according to the present disclosure, and is used exclude light paths from the hologram calculation.

UK patent application 2112213.0, filed 26 Aug. 2021 and incorporated herein by reference, discloses a second method based on a modified Gerchberg-Saxton type algorithm which includes steps of light field cropping in accordance with pupils of the optical system during hologram calculation. The cropping of the light field may be considered to correspond to the determination of a limiting aperture according to the present disclosure.

UK patent application 2118911.3, filed 23 Dec. 2021 and also incorporated herein by reference, discloses a third method of calculating a hologram which includes a step of determining a region of a so-called extended modulator formed by a hologram replicator. The region of the extended modulator may also be considered to be an aperture in accordance with the present disclosure.

In some embodiments, there is provided a real-time engine arranged to receive image data and calculate holograms in real-time using the algorithm. In some embodiments, the image data is a video comprising a sequence of image frames. In other embodiments, the holograms are pre-calculated, stored in computer memory and recalled as needed for display on a SLM. That is, in some embodiments, there is provided a repository of predetermined holograms.

Broadly, the present disclosure relates to image projection. In particular, it relates to a method of image projection and an image projector which comprises a display device. The present disclosure also relates to a projection system comprising the image projector and a viewing system, in which the image projector projects or relays light from the display device to the viewing system. The present disclosure is equally applicable to a monocular and binocular viewing system. The viewing system may comprise a viewer's eye or eyes. The viewing system comprises an optical element having optical power (e.g., lens or lenses of the human eye(s)) and a viewing plane (e.g., retina or retinas of the human eye(s)). The projector may be referred to as a ‘light engine’. The display device and the image formed (or perceived) using the display device are spatially separated from one another. The image is formed, or perceived by a viewer, on a display plane. In some embodiments, the image is a virtual image and the display plane may be referred to as a virtual image plane. In other embodiments, the image is a real image formed by holographic reconstruction and the image is projected or relayed to the viewing plane. In these other embodiments, spatially modulated light of an intermediate holographic reconstruction formed either in free space or on a screen or other light receiving surface between the display device and the viewer is propagated to the viewer. In both sets of embodiments, an image is formed by illuminating a diffractive pattern (e.g., hologram or kinoform) displayed or provided on the display device.

The display device of embodiments described herein comprises pixels. The pixels of the display may display a diffractive pattern or structure that diffracts light. The diffracted light may form an image at a plane spatially separated from the display device. In accordance with well-understood optics, the magnitude of the maximum diffraction angle is dictated by the size of the pixels and other factors such as the wavelength of the light.

In some embodiments, the display device is a SLM such as liquid crystal on silicon (“LCOS”) SLM. Light propagates over a range of diffraction angles (for example, from zero to the maximum diffractive angle) from the LCOS towards a viewing entity/system, such as a camera or an eye. In some embodiments, magnification techniques may be used to increase the range of available diffraction angles beyond the conventional maximum diffraction angle of the LCOS.

In some embodiments, the (light of a) hologram itself is propagated to the eyes. For example, spatially modulated light of the hologram (that has not yet been fully transformed into a holographic reconstruction, i.e. an image)—that may hereinafter be said to be “encoded” with or by the hologram—is propagated directly to the viewer's eyes. A real or virtual image may thus be perceived by the viewer. In these embodiments, there is no intermediate holographic reconstruction or image formed between the display device and the viewer. It is hereinafter considered that, in these embodiments, the lens of the eye performs a hologram-to-image conversion or transform. The projection system, or light engine, may be configured such that the viewer is able, or expected, to look directly at the display device.

Reference is made herein to a “light field” which is a “complex light field”. The term “light field” merely indicates a pattern of light having a finite size in at least two orthogonal spatial directions, e.g. x and y. The word “complex” is used herein merely to indicate that the light at each point in the light field may be defined by an amplitude value and a phase value, and may therefore be represented by a complex number or a pair of values. For the purpose of hologram calculation, the complex light field may be a two-dimensional array of complex numbers, wherein the complex numbers define the light intensity and phase at a plurality of discrete locations within the light field.

In accordance with the principles of well-understood optics, the range of angles of light propagating from a display device that can be viewed, by an eye or other viewing entity or system, varies with the distance between the display device and the viewing entity. At a 1-metre viewing distance, for example, only a small range of angles from an LCOS can propagate through an eye's pupil to form an image at the retina for a given eye position. The range of angles of light rays which can successfully propagate through an eye's pupil to form an image at the retina for a given eye position determines the portion of the image that is ‘visible’ to the viewer. In other words, not all parts of the image are visible from any one point on the viewing plane (e.g., from any one eye position within a viewing window such as an eye-box.)

In some embodiments, the image perceived by a viewer is a virtual image that appears upstream of the display device—that is, the viewer perceives the image as being further away from them than is the display device. Conceptually, it may therefore be considered that the viewer is looking at a virtual image through an ‘display device-sized window’, which may be very small, for example 1 cm in diameter, at a relatively large distance, e.g., 1 m. Moreover, the user views the display device-sized window via the pupil(s) of their eye(s), which tend also to be relatively small. As such, the field of view becomes small and the specific angular range of light that can be viewed depends heavily on eye position at any given time.

A pupil expander addresses the problem of increasing the range of angles of light rays propagated from the display device which can successfully propagate through an eye's pupil to form an image. The display device is generally relatively small and the projection distance relatively large. In some embodiments, the projection distance is at least one, e.g. at least two, orders of magnitude greater than the diameter, or width, of the entrance pupil and/or aperture of the display device (i.e., size of the array of pixels).

Use of a pupil expander increases the viewing area (i.e., user's eye-box) laterally, thus enabling some movement of the eye/s to occur, whilst still enabling the user to see the image. As the skilled person will appreciate, in an imaging system, the viewing area (user's eye box) is the area in which a viewer's eyes can perceive the image. The present disclosure encompasses non-infinite virtual image distances—that is, near-field virtual images.

Conventionally, a two-dimensional pupil expander comprises one or more one-dimensional optical waveguides each formed using a pair of opposing reflective surfaces, in which the output light from a surface forms a viewing window or eye-box. Light received from the display device (e.g., spatially modulated light from a LCOS) is replicated by the waveguides, or each waveguide, so as to increase the field of view (or viewing area) in at least one dimension. In particular, the waveguide enlarges the viewing window due to the generation of extra rays or “replicas” by division of amplitude of the incident wavefront.

The display device of embodiments described herein may have an active or display area having a first dimension that may be less than 10 cm, e.g. less than 5 cm or less than 2 cm. The propagation distance between the display device and viewing system may be greater than 1 m, e.g. greater than 1.5 m or greater than 2 m. The optical propagation distance within the waveguide may be up to 2 m, e.g. up to 1.5 m or up to 1 m. The method may include receiving an image and determining a corresponding hologram of sufficient quality in a timeframe of less than 20 ms, e.g. less than 15 ms or less than 10 ms.

In some embodiments-described by way of example only-a hologram is configured to route light into a plurality of channels, each channel corresponding to a different part (i.e. sub-area) of an image. The channels formed by the diffractive structure are referred to herein as “hologram channels” merely to reflect that they are channels of light encoded, by the hologram, with image information. It may be said that the light of each channel is in the hologram domain rather than the image or spatial domain. In some embodiments, the hologram is a Fourier or Fourier transform hologram and the hologram domain is therefore the Fourier or frequency domain. The hologram may equally be a Fresnel or Fresnel transform hologram. The hologram may also be a point cloud hologram. The hologram is described herein as routing light into a plurality of hologram channels to reflect that the image that can be reconstructed from the hologram has a finite size and can be arbitrarily divided into a plurality of image sub-areas, wherein each hologram channel corresponds to each image sub-area. Importantly, the hologram of this example is characterised by how it distributes, or divides, the image content when illuminated. Specifically, and uniquely, the hologram according to embodiments described herein divides the image content by angle. That is, each point on the image is associated with a unique pair of light ray angles in the spatially modulated light formed by the hologram when illuminated, since the hologram is two-dimensional. For the avoidance of doubt, such hologram characteristics are non-conventional. The spatially modulated light formed by this special type of hologram, when illuminated, may be divided into a plurality of hologram channels, wherein each hologram channel is defined by a range of light ray angles (in two dimensions). It will be associated with the spatially modulated light will itself be associated with a respective part or sub-area of the image. That is, all the information needed to reconstruct that part or sub-area of the image is contained within a particular, corresponding sub-range of angles of the spatially modulated light formed from the hologram of the image. When the spatially modulated light is observed as a whole, there is not necessarily any evidence, e.g. observable or easily detectable indication, of a plurality of discrete light channels.

Nevertheless, such a hologram having the aforementioned non-conventional characteristics may still be identifiable. For example, if only a continuous part or sub-area of the spatially modulated light formed by the hologram is reconstructed, only a sub-area of the image should be visible. Hence, if a different continuous part or sub-area of the spatially modulated light is reconstructed, a different sub-area of the image should be visible. A further identifying feature of this type of hologram is that the shape of the cross-sectional area of any hologram channel substantially corresponds to (i.e. is substantially the same as) the shape of the entrance pupil, at least at the correct plane for which the hologram was calculated. However, the size of the channel cross-sectional area may differ from that of the entrance pupil. Each hologram channel extends from the hologram at a different angle or range of angles. Whilst these are exemplary ways of characterising or identifying this type of hologram, other appropriate ways may be used. In summary, the hologram disclosed herein is characterised and identifiable by how the image content is distributed within the light encoded by the hologram. Again, for the avoidance of any doubt, reference herein to a hologram configured to direct light or angularly-divide an image into a plurality of hologram channels is made by way of example only, and the invention of the present disclosure is equally applicable to pupil expansion of any type of holographic light field or even any type of diffractive or diffracted light field.

The system of embodiments described herein may be provided in a compact and streamlined physical form. This enables the system to be suitable for a broad range of real-world applications, including those for which space is limited and real-estate value is high. For example, it may be implemented in a HUD, such as a vehicle or automotive HUD.

In accordance with the present disclosure, pupil expansion is provided for diffracted or diffractive light, which light may comprise diverging ray bundles. The diffracted light field may be defined by a “light cone”. Thus, the size of the diffracted light field (as defined on a two-dimensional plane) increases with propagation distance from the corresponding diffractive structure (i.e., display device). It can be said that the pupil expander(s) replicate the hologram or form at least one replica of the hologram, to convey that the light delivered to the viewer is spatially modulated in accordance with a hologram.

In some embodiments, two one-dimensional waveguide pupil expanders are provided, each one-dimensional waveguide pupil expander being arranged to effectively increase the size of the exit pupil of the system by forming a plurality of replicas or copies of the exit pupil (or light of the exit pupil) of the SLM. The exit pupil may be understood to be the physical area from which light is output by the system. It may also be said that each waveguide pupil expander is arranged to expand the size of the exit pupil of the system. It may also be said that each waveguide pupil expander is arranged to expand/increase the size of the eye box within which a viewer's eye can be located, in order to receive, i.e. see, light that is output by the system.

The hologram formed in accordance with the embodiments described herein angularly divides the image content to provide a plurality of hologram channels which may have a cross-sectional shape defined by an aperture of the optical system. The hologram is calculated and formed so as to provide this particular channeling of the diffracted light field. In some embodiments, such hologram calculation is achieved by considering an aperture (virtual or real) of the optical system, as described above.

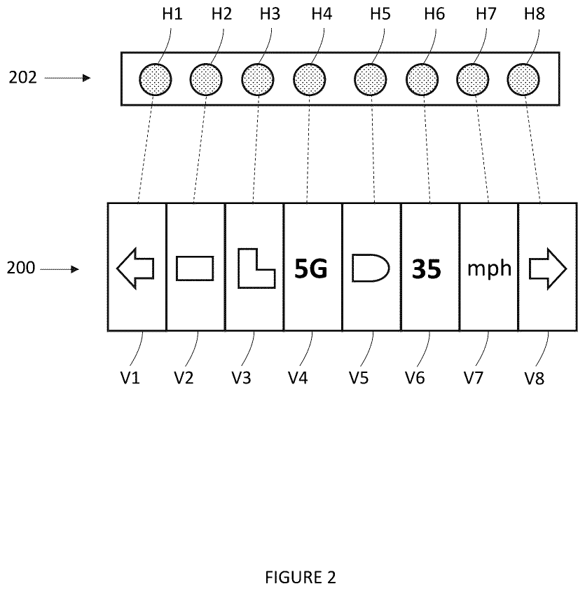

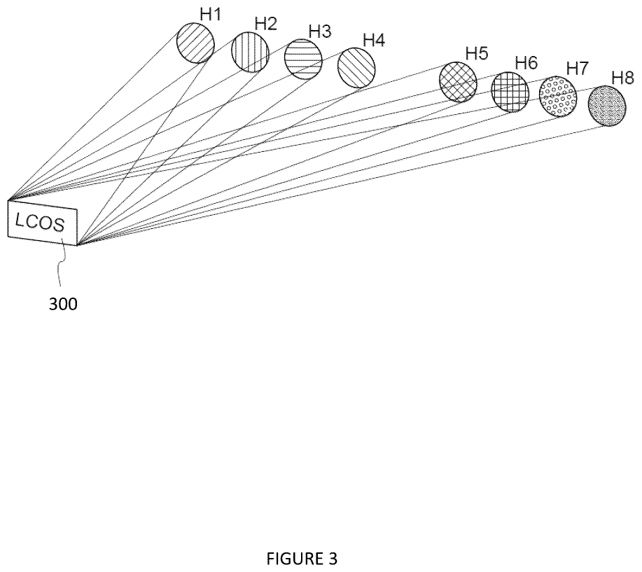

FIGS. 2 and 3 illustrate an example of this type of hologram that may be used in conjunction with a pupil expander as disclosed herein. However, this example should not be regarded as limiting with respect to the invention of the present disclosure.

FIG. 2 depicts an image 200 for projection comprising eight image areas or components, indicated in FIG. 2 by the respective alphanumeric reference characters V1-V8. FIG. 2 shows eight image components, by way of example only; the image 200 may be divided into any number of components. FIG. 2 also depicts an encoded light pattern 202 (i.e., hologram) that can reconstruct the image 200—e.g., when transformed by the lens of a suitable viewing system. The encoded light pattern 202 comprises first to eighth sub-holograms or components, indicated in FIG. 2 by the respective alphanumeric reference characters H1-H8, corresponding to the first to eighth image areas or components V1-V8.

FIG. 2 further illustrates that the hologram 202 may decompose the image content by angle. The hologram may therefore be characterised by the channeling of light that it performs. This is further illustrated in FIG. 3.

Specifically, FIG. 3 illustrates that the hologram 202, and more particularly a LCOS 300, directs light into a plurality of discrete areas H1-H8. The discrete areas are discs in the example shown but other shapes are envisaged. The size and shape of the optimum disc may, after propagation through the waveguide, be related to, e.g. dictated by, the size and shape of an aperture of the optical system such as the entrance pupil of the viewing system.

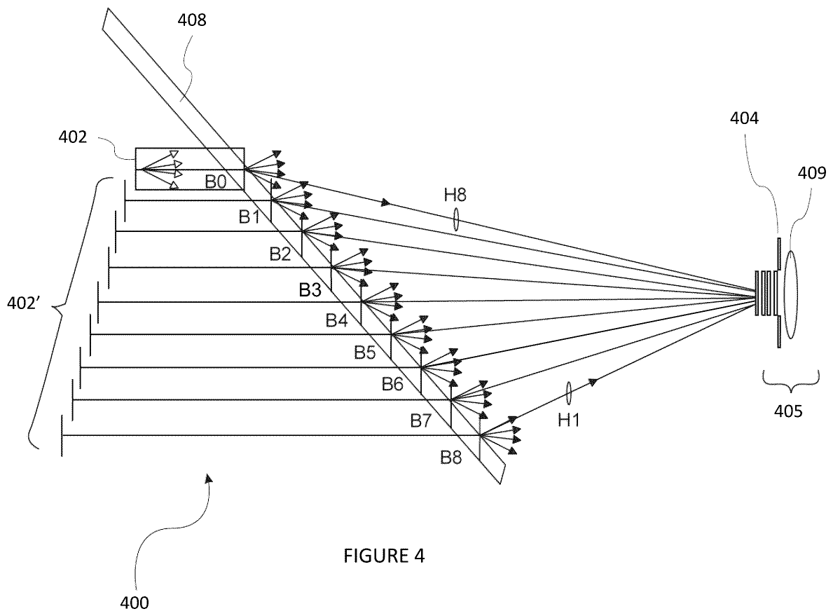

FIG. 4 depicts a system 400, including a display device that displays a hologram that has been calculated as illustrated in FIGS. 2 and 3.

The system 400 comprises a display device, which in this arrangement comprises an LCOS 402, e.g. the LCOS 300 illustrated in FIG. 3. The LCOS 402 is arranged to display a modulation pattern (or “diffractive pattern”) comprising the hologram and to project light that has been holographically encoded towards an eye 405 of a user. The eye 405 comprises a pupil that acts as an aperture 404, a lens 409, and a retina (not shown) that acts as a viewing plane. The system 400 includes a light source (not shown) arranged to illuminate the LCOS 402. The lens 409 of the eye 405 performs a hologram-to-image transformation. The light source may be of any suitable type. For example, the light source may comprise a laser light source.

The viewing system 400 further comprises a waveguide 408 positioned between the LCOS 402 and the eye 405. The presence of the waveguide 408 enables all angular content from the LCOS 402 to be received by the eye, even at the relatively large projection distance shown. This is because the waveguide 408 acts as a pupil expander, in a manner that is well known and thus described only briefly herein.

In brief, the waveguide 408 shown in FIG. 4 comprises a substantially elongate formation. In this embodiment, the waveguide 408 comprises an optical slab of refractive material, but other types of waveguide are also well known and may be used. The waveguide 408 is located so as to intersect with the light cone (i.e., the diffracted light field) that is projected from the LCOS 402, for example at an oblique angle. In this embodiment, the size, location, and position of the waveguide 408 are configured to ensure that light from each of the eight ray bundles, within the light cone, enters the waveguide 408. Light from the light cone enters the waveguide 408 via its first planar surface (located nearest the LCOS 402) and is guided at least partially along the length of the waveguide 408, before being emitted via its second planar surface, substantially opposite the first surface (located nearest the eye). As will be well understood, the second planar surface is partially reflective, partially transmissive. In other words, when each ray of light travels within the waveguide 408 from the first planar surface and hits the second planar surface, some of the light will be transmitted out of the waveguide 408 and some will be reflected by the second planar surface, back towards the first planar surface. The first planar surface is reflective, such that all light that hits it, from within the waveguide 408, will be reflected back towards the second planar surface. Therefore, some of the light may simply be refracted between the two planar surfaces of the waveguide 408 before being transmitted, whilst other light may be reflected, and thus may undergo one or more reflections, (or ‘bounces’) between the planar surfaces of the waveguide 408, before being transmitted.

FIG. 4 shows a total of nine “bounce” points, indicated by the respective alphanumeric reference characters B0-B8, along the length of the waveguide 408. Although light relating to all points of the image (V1-V8, as shown in FIG. 2) is transmitted out of the waveguide 408 at each bounce point from the second planar surface of the waveguide 408, only the light from one angular part of the image (e.g. light of one of V1 to V8) has a trajectory that enables it to reach the eye 405, from each respective bounce” point, B0-B8. Moreover, light from a different angular part of the image, V1-V8, reaches the eye 405 from each respective bounce point B0-B8. Therefore, in the embodiment of FIG. 4, each angular channel of encoded light reaches the eye 405 only once, from the waveguide 408.

The waveguide 408 forms a plurality of replicas of the hologram, at the respective bounce points B1-B8 along its length, corresponding to the direction of pupil expansion.

As indicated in FIG. 4, the plurality of replicas may be extrapolated back, in a straight line, to a corresponding plurality of replica or virtual display devices 402′. This process corresponds to the step of “unfolding” an optical path within the waveguide 408, so that a light ray of a replica is extrapolated back to a “virtual surface” without internal reflection within the waveguide. Thus, the light of the expanded exit pupil may be considered to originate from a virtual surface (also called an “extended modulator” herein) comprising the display device 402 and the replica display devices 402′.

Although virtual images, which require the eye to transform received modulated light in order to form a perceived image, have generally been discussed herein, the methods and arrangements described herein can be applied to real images.

Whilst the arrangement shown in FIG. 4 includes a single waveguide that provides pupil expansion in one dimension, pupil expansion may be provided in more than one dimension, for example in two dimensions. Moreover, whilst the embodiment of FIG. 4 uses a hologram that has been calculated to create channels of light, each corresponding to a different portion of an image, the present disclosure and the systems that are described herein are not limited to such a hologram type.

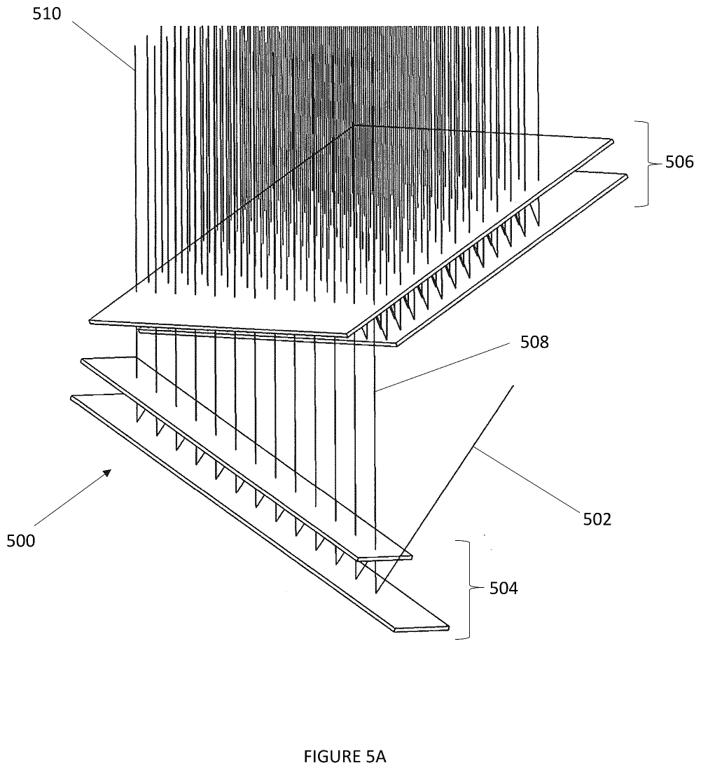

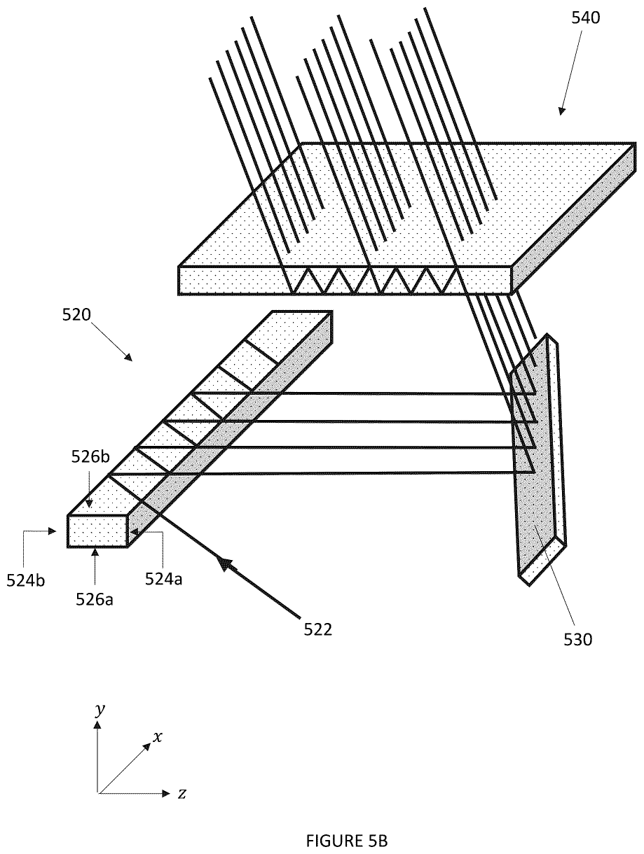

FIG. 5A depicts a perspective view of a system 500 comprising two replicators, 504, 506 arranged for expanding a collimated light beam 502 in two dimensions.

In the system 500 of FIG. 5A, the first replicator 504 comprises a first pair of surfaces, stacked parallel to one another, and arranged to provide replication—i.e., pupil expansion—in a similar manner to the waveguide 408 of FIG. 4. The first pair of surfaces are similarly (in some embodiments, identically) sized and shaped to one another and are substantially elongate in one direction. The collimated light beam 502 is directed towards an input on the first replicator 504. Via a process of internal reflection between the two surfaces, and partial transmission of light from each of a plurality of output points on one of the surfaces (the upper surface, as shown in FIG. 5A), which will be familiar to the skilled reader, light of the light beam 502 is replicated in a first direction, along the length of the first replicator 504. Thus, a first plurality of replica light beams 508 is emitted from the first replicator 504, towards the second replicator 506.

The second replicator 506 comprises a second pair of surfaces stacked parallel to one another, arranged to receive each of the collimated light beams of the first plurality of light beams 508 and further arranged to provide replication—or pupil expansion—by expanding each of those light beams in a second direction, substantially orthogonal to the first direction. The first pair of surfaces are similarly (in some cases, identically) sized and shaped to one another and are substantially rectangular. The second replicator has rectangular shape in order to receive the first plurality of light beams 508 along a first length in the first direction, and to provide replication along a second length in the second direction. Due to a process of internal reflection between the two surfaces, and partial transmission of light from each of a plurality of output points on one of the surfaces (specifically, the uppermost surface, as shown in FIG. 5A), light of each light beam within the first plurality of light beams 508 is replicated in the second direction. Thus, a second plurality of light beams 510 is emitted from the second replicator 506, wherein the second plurality of light beams 510 comprises replicas of the input light beam 502 along each of the first direction and the second direction. Thus, the second plurality of light beams 510 may be regarded as comprising a two-dimensional grid, or array, of replica light beams.

Thus, it can be said that the first and second replicators 504, 505 of the embodiment of FIG. 5A combine to provide a two-dimensional replicator (or a “two-dimensional pupil expander”). The replica light beams 510 may be emitted along an optical path to an expanded eye-box of a display system, such as a HUD.

In the system of FIG. 5A, the first replicator 504 is a waveguide comprising a pair of elongate rectilinear reflective surfaces, stacked parallel to one another, and, similarly, the second replicator 504 is a waveguide comprising a pair of rectangular reflective surfaces, stacked parallel to one another. In other systems, the first replicator may be a solid elongate rectilinear waveguide and the second replicator may be a solid planar rectangular shaped waveguide, wherein each waveguide comprises an optically transparent solid material such as glass. In this case, the pair of parallel reflective surfaces are formed by a pair of opposed major sidewalls optionally comprising respective reflective and reflective-transmissive surface coatings, familiar to the skilled reader.

FIG. 5B depicts a perspective view of a system 500 comprising two replicators, 520, 540 arranged for replicating a light beam 522 in two dimensions, in which the first replicator is a solid elongated waveguide 520 and the second replicator is a solid planar waveguide 540.

In the system 500 of FIG. 5B, the first replicator/waveguide 520 is arranged such that each surface of its pair of elongate parallel reflective surfaces 524a, 524b is perpendicular to the plane of the second replicator/waveguide 540. Accordingly, the system comprises an optical coupler arranged to couple light from an output port of first replicator 520 into an input port of the second replicator 540. In the illustrated arrangement, the optical coupler is a planar/fold mirror 530 arranged to fold or turn the optical path of light to achieve the required optical coupling from the first replicator to the second replicator. As shown in FIG. 5B, the mirror 530 is arranged to receive light—comprising a one-dimensional array of replicas extending in a first dimension—from the output port/reflective-transmissive surface 524a of the first replicator/waveguide 520. The mirror 530 is tilted thereby to redirect the received light onto an optical path to an input port in the (fully) reflective surface of second replicator 540 at an angle to provide waveguiding and replica formation, along its length in a second dimension orthogonal to the first dimension. It will be appreciated that the mirror 530 is one example of an optical element that can redirect the light in the manner shown, and that in some embodiments one or more other elements may be used instead to perform this task.

In this embodiment, the (partially) reflective-transmissive surface 524a of the first replicator 520 is adjacent the input port of the first replicator/waveguide 520 that receives input beam 522 at an angle, thereby to provide waveguiding and replica formation along its length in the first dimension. Thus, the input port of first replicator/waveguide 520 is positioned at an input end thereof at the same surface as the reflective-transmissive surface 524a. The skilled reader will understand that the input port of the first replicator/waveguide 520 may, in this and other embodiments, be at any other suitable position.

Accordingly, the arrangement embodied in FIG. 5B enables the first replicator 520 and the mirror 530 to be provided as part of a first relatively thin layer in a plane defined by the first dimension and a third dimension orthogonal to both the first and second dimensions (the plane being illustrated as the x-z plane in FIG. 5B). In particular, the size or “height” of a first planar layer, in which the first replicator 520 is located, in the second dimension (illustrated as the y dimension in FIG. 5B) is reduced. The mirror 530 is configured to direct the light away from a first layer/plane, in which the first replicator 520 is located (i.e., the first planar layer), and direct it towards a second layer/plane, located above and substantially parallel to the first layer/plane, in which the second replicator 540 is located (i.e. a second planar layer). Thus, the overall size or “height” (in the second dimension, illustrated as the y-dimension) of the system, comprising the sum of the respective heights of the first and second replicators 520, 540 and the mirror 530 located in the stacked first and second planar layers defined by the first and third dimensions (illustrated in FIG. 5B as an x-z plane). The skilled reader will understand that many variations of the arrangement of FIG. 5B for implementing the present disclosure are possible and contemplated.

The image projector according to this embodiment may be arranged to project a diverging or diffracted light field. In some embodiments, the light field is encoded with a hologram. In some embodiments, the diffracted light field comprises diverging ray bundles. In some embodiments, the image formed by the diffracted light field is a virtual image.

In some embodiments, the first pair of parallel or complementary surfaces comprises elongate or elongated surfaces, i.e. surfaces which are relatively long along a first dimension and relatively short along a second, orthogonal dimension, e.g. surfaces which are relatively short along each of two other dimensions, with each dimension being substantially orthogonal to each of the respective others. The process of reflection/transmission of the light between/from the first pair of parallel surfaces is arranged to cause the light to propagate within the first waveguide pupil expander, with the general direction of light propagation being in the direction along which the first waveguide pupil expander is relatively long (i.e., in its elongate direction).

There is disclosed herein embodiments including a system that forms an image using diffracted light and provides an eye-box size and field of view suitable for real-world application—e.g. in the automotive industry, by way of a HUD. The diffracted light is light forming a holographic reconstruction of the image from a diffractive structure—e.g. hologram such as a Fourier or Fresnel hologram. The use of diffraction and a diffractive structure necessitates a display device with a high density of very small pixels (e.g., 1 micrometer) which, in practice, requires a small display device (e.g. 1 cm). The present inventors have addressed a problem of providing 2D pupil expansion with a diffracted light field, e.g. diffracted light comprising diverging (not collimated) ray bundles.

In some embodiments, the display system comprises a display device-such as a pixelated display device, for example SLM or LCOS SLM-arranged to provide or form the diffracted or diverging light. In such aspects, the aperture of the SLM is a limiting aperture of the system. That is, the aperture of the SLM-more specifically, the size of the area delimiting the array of light modulating pixels comprised within the SLM-determines the size (e.g. spatial extent) of the light ray bundle that can exit the system. In accordance with this disclosure, it is stated that the exit pupil of the system is expanded to reflect that the exit pupil of the system (that is limited by the small display device having a pixel size for light diffraction) is made larger, i.e. greater in spatial extent, by the use of at least one pupil expander.

In some embodiments, the diffracted or diverging light field may be said to have “a light field size”, defined in a direction substantially orthogonal to a propagation direction of the light field. Because the light is diffracted/diverging, the light field size increases with propagation distance.

In some embodiments, the diffracted light field is spatially-modulated in accordance with a hologram. In other words, in such aspects, the diffractive light field comprises a “holographic light field”. The hologram may be displayed on a pixelated display device. The hologram may be a computer-generated hologram (CGH). The hologram may be a Fourier hologram or a Fresnel hologram or a point-cloud hologram, or any other suitable type of hologram. The hologram may, optionally, be calculated such that the hologram form channels of hologram light, with each channel corresponding to a different respective portion of an image that is intended to be viewed (or perceived, if the image is a virtual image) by the viewer. The pixelated display device may be configured to display a plurality of different holograms, in succession or in sequence. Each of the aspects and embodiments disclosed herein may be applied to the display of multiple holograms.

In some embodiments, the output port of the first waveguide pupil expander may be coupled to an input port of a second waveguide pupil expander. The second waveguide pupil expander may be arranged to guide the diffracted light field—including some of, and preferably most of, and preferably all of, the replicas of the light field that are output by the first waveguide pupil expander—from its input port to a respective output port by internal reflection between a third pair of parallel surfaces of the second waveguide pupil expander.

In some embodiments, the first waveguide pupil expander may be arranged to provide pupil expansion, or replication, in a first direction and the second waveguide pupil expander may be arranged to provide pupil expansion, or replication, in a second, different direction. The second direction may be substantially orthogonal to the first direction. The second waveguide pupil expander may be arranged to preserve the pupil expansion that the first waveguide pupil expander has provided in the first direction and to expand (or, replicate) some of, preferably most of, preferably all of, the replicas that it receives from the first waveguide pupil expander in the second, different direction. The second waveguide pupil expander may be arranged to receive the light field directly or indirectly from the first waveguide pupil expander. One or more other elements may be provided along the propagation path of the light field between the first and second waveguide pupil expanders.

In some embodiments, the first waveguide pupil expander may be substantially elongate and the second waveguide pupil expander may be substantially planar. The elongate shape of the first waveguide pupil expander may be defined by a length along a first dimension. The planar, or rectangular, shape of the second waveguide pupil expander may be defined by a length along a first dimension and a width, or breadth, along a second dimension substantially orthogonal to the first dimension. A size, or length, of the first waveguide pupil expander along its first dimension make correspond to the length or width of the second waveguide pupil expander along its first or second dimension, respectively. A first surface of the pair of parallel surfaces of the second waveguide pupil expander, which second surface comprises an input port, may be shaped, sized, and/or located so as to correspond to an area defined by an output port on the first surface of the pair of parallel surfaces on the first waveguide pupil expander, such that the second waveguide pupil expander is arranged to receive each of the replicas output by the first waveguide pupil expander.

In some embodiments, the first and second waveguide pupil expander may collectively, i.e. together, provide pupil expansion in a first direction and in a second direction perpendicular to the first direction, wherein, optionally, a plane containing the first and second directions is substantially parallel to a plane of the second waveguide pupil expander. In other words, the first and second dimensions that respectively define the length and breadth of the second waveguide pupil expander may be parallel to the first and second directions, respectively, or parallel to the second and first directions, respectively, in which the waveguide pupil expanders provide pupil expansion. The combination of the first waveguide pupil expander and the second waveguide pupil expander may be generally referred to as a “pupil expander”.

It may be said that, in some embodiments, the expansion/replication provided by the first and second waveguide expanders has the effect of expanding an exit pupil of the display system in each of two directions. An area defined by the expanded exit pupil may, in turn, define an expanded eye-box area, from which the viewer can receive light of the diffracted or diverging light field. The eye-box area may be said to be located on, or define, a viewing plane.

In some embodiments, the two directions in which the exit pupil is expanded may be coplanar with, or parallel to, the first and second directions in which the first and second waveguide pupil expanders provide replication/expansion. Alternatively, in arrangements that comprise other elements such as an optical combiner, for example the windscreen (or, windshield) of a vehicle, the exit pupil may be regarded as being an exit pupil from that other element, such as from the windscreen. In such arrangements, the exit pupil may be non-coplanar and non-parallel with the first and second directions in which the first and second waveguide pupil expanders provide replication/expansion. For example, the exit pupil may be substantially perpendicular to the first and second directions in which the first and second waveguide pupil expanders provide replication/expansion.

In some embodiments, the viewing plane, and/or the eye-box area, may be non-coplanar or non-parallel to the first and second directions in which the first and second waveguide pupil expanders provide replication/expansion. For example, a viewing plane may be substantially perpendicular to the first and second directions in which the first and second waveguide pupil expanders provide replication/expansion.

In order to provide suitable launch conditions to achieve internal reflection within the first and second waveguide pupil expanders, an elongate, i.e. longest, dimension of the first waveguide pupil expander may be tilted relative to the other dimensions of the second waveguide pupil expander.

The inventors have realised that, advantageously, projecting a hologram to the eye-box allows optical compensation to be encoded in the hologram (see, for example, European patent 2936252 incorporated herein by reference). The present disclosure is compatible with holograms that compensate for the complex curvature of an optical combiner used as part of the projection system. In some embodiments, the optical combiner is the windscreen of a vehicle. Full details of this approach are provided in European patent 2936252, incorporated herein by reference, and are not repeated here and are merely exemplary of configurations which may benefit from the teachings of the present disclosure.

The inventors have realised that the present disclosure is also compatible with optical configurations that include a control device (e.g., light shuttering device) to control the delivery of light from a light channelling hologram to the viewer. The holographic projector according to the present invention may further comprise a control device arranged to control the delivery of angular channels to the eye-box position. British patent application 2108456.1, filed 14 Jun. 2021 and incorporated herein by reference, discloses at least one waveguide pupil expander and control device. The reader will understand from at least this prior disclosure that the optical configuration of the control device is fundamentally based upon the eye-box position of the user and is compatible with any hologram calculation method that achieves the light channelling described herein. It may be said that the control device is a light shuttering or aperturing device. The light shuttering device may comprise a 1D array of apertures or windows, wherein each aperture or window independently switchable between a light transmissive and a light non-transmissive state thereby to control the delivery of hologram light channels, and their replicas, to the eye-box. Each aperture or window may comprise a plurality of liquid crystal cells or pixels.

High power laser diodes are typically edge emitters with a single broad ridge from which the light is emitted. However, the inventors have realised that, in the interests of obtaining high power, it is also possible to fabricate multiple emitting ridges in close proximity to one another. The inventors have further realised that use of such a light source in a holographic display offers advantages as compared to a single broad stripe emitter.

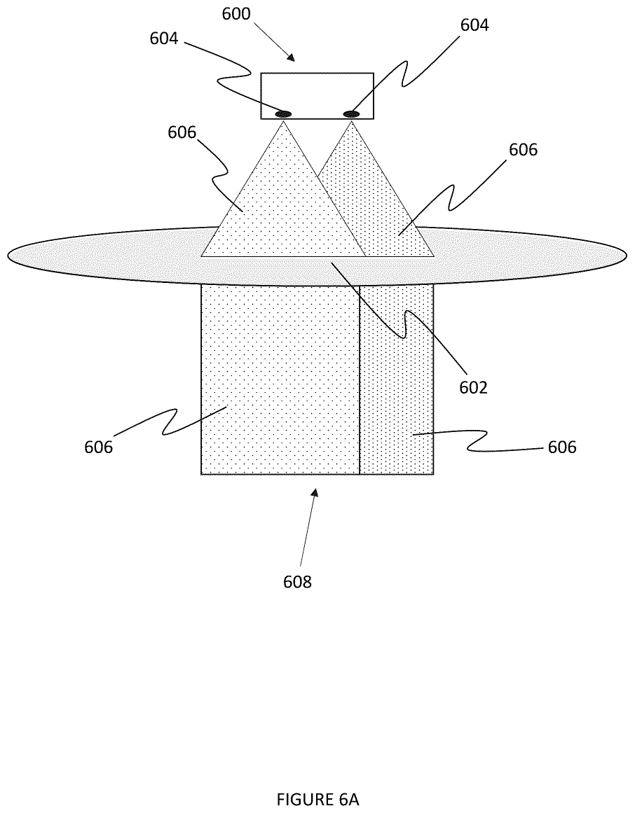

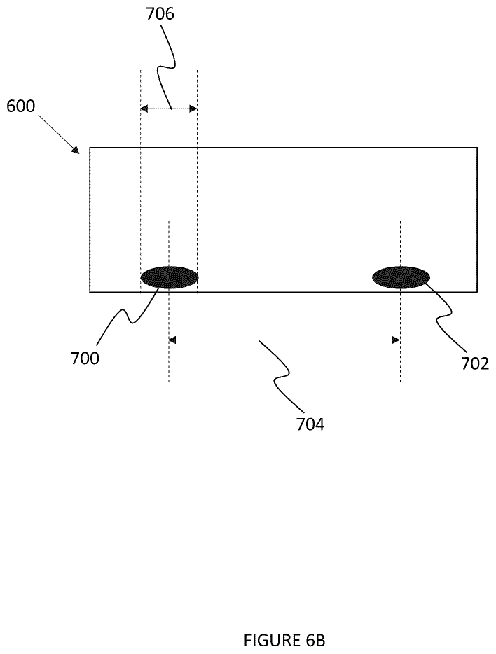

FIG. 6A depicts a multi-emitter laser 600 illuminating an optic 602. The multi-emitter laser 600 comprises a plurality of emitters 604, each of which emits light 606, i.e. a respective beamlet 606, which is of substantially similar wavelength to, but nonetheless incoherent with, that of the other emitter(s) 604.

Light from the emitters is collimated by the optic 602, thereby to produce a continuous beam 608 towards the LCOS, in which beam 608 the beamlets 606 are substantially parallel and at least partially overlap. The respective speckle patterns of the plurality of emitters tend to superpose and, by virtue of the incoherence of the beamlets with each other, combine in intensity rather than amplitude and phase. As a result, the superposed speckle patterns tend to provide improved illumination of the hologram, resulting in an image which has reduced non-uniformity, i.e. less noise, from laser speckle.

Providing multiple emitters on the same laser chip tends to advantageously enable higher power to be efficiently coupled onto the spatial light modulator of the holographic display from a small range of angles. As a result, high resolution in the holographic reconstruction tends to be achieved.

Advantageously, providing multiple emitters on the same laser chip tends to enable higher power to be efficiently coupled onto the LCOS of the holographic display from a small range of angles. This is particularly beneficial for maintaining the high resolution of the display.

Advantageously, a single collimation optic 602 may be used, simplifying the design compared to, e.g., coupling fibre-coupled single emitters, each of which would require its own collimating optic, to give the same output as the multi-emitting laser.

Furthermore, the emission of each ridge of the multi-emitter tends to advantageously emit light with a substantially similar spectrum because the wavelength of emission is dominated, i.e. determined in large part, by the precise material composition of the emitting layer. This is in contrast to the case in which multiple different chips are used, which tends to result in a wavelength spread due to variations in the doping process during fabrication of the emitting layer. A wavelength spread is detrimental to image quality due to the diffractive nature of the LCoS. More specifically, different wavelengths are diffracted to different angles/extents, resulting in a blurring of the content at the edges of the field of view.

Advantageously, the close proximity of the multiple laser emitters tends to allow for maintenance of high uniformity of illumination of the LCOS while increasing the total optical power.

FIG. 6B shows a schematic illustration of the multi-emitter laser 600. In particular, FIG. 6B depicts a first emitter 700 and a second emitter 702. In FIG. 6B, only two emitters are illustrated, such that the multi-emitter 600 illustrated may be considered a double-emitter laser 600. However, in this and other embodiments, the multi-emitter laser 600 may comprise further emitters, such that the multi-emitter laser 600 comprises a plurality of emitters other than two, e.g. three emitters, or four emitters, or five emitters, or more emitters than five.

In this embodiment, a distance 704 between the first emitter 700 and the second emitter 702 is between 10 micrometres and 200 micrometres, e.g. between 50 micrometres and 150 micrometres, e.g. between 70 micrometres and 130 micrometres. In other embodiments, the distance 704 may be a different distance, e.g. less than 10 micrometres, or e.g. greater than 200 micrometres.

In this embodiment, a width 706 of the first emitter 700, which may be equal to a width of the second emitter 702, is between 1 micrometre and 50 micrometres, e.g. between 2 micrometres and 20 micrometres, e.g. between 5 micrometres and 15 micrometres, e.g. 10 micrometres. In other embodiments, the width 706 may be a different width, e.g. less than 1 micrometres, or e.g. greater than 50 micrometres.

The methods and processes described herein may be embodied on a computer-readable medium. The term “computer-readable medium” includes a medium arranged to store data temporarily or permanently such as random-access memory (RAM), read-only memory (ROM), buffer memory, flash memory, and cache memory. The term “computer-readable medium” shall also be taken to include any medium, or combination of multiple media, that is capable of storing instructions for execution by a machine such that the instructions, when executed by one or more processors, cause the machine to perform any one or more of the methodologies described herein, in whole or in part.

The term “computer-readable medium” also encompasses cloud-based storage systems. The term “computer-readable medium” includes, but is not limited to, one or more tangible and non-transitory data repositories (e.g., data volumes) in the example form of a solid-state memory chip, an optical disc, a magnetic disc, or any suitable combination thereof. In some example embodiments, the instructions for execution may be communicated by a carrier medium. Examples of such a carrier medium include a transient medium (e.g., a propagating signal that communicates instructions).

It will be apparent to those skilled in the art that various modifications and variations can be made without departing from the scope of the appended claims. The present disclosure covers all modifications and variations within the scope of the appended claims and their equivalents.

What is claimed is:

1. A system comprising a holographic projector, wherein the holographic projector comprises:
a display device configured to display a hologram of a picture;
a laser diode chip comprising a plurality of emitters configured to emit a plurality of beamlets, wherein each emitter of the plurality of emitters is arranged to form a respective beamlet, wherein individual beamlets are incoherent with each other such that they form different respective speckle patterns; and
an optic configured to receive the plurality of beamlets and form a continuous beam in which beamlets of the plurality of beamlets at least partially overlap such that the different respective speckle patterns combine through superposition of intensity rather than amplitude and phase, wherein the holographic projector is configured to illuminate the hologram with the continuous beam to form a holographic reconstruction of the picture, and wherein the superposition of the intensity of the different respective speckle patterns reduces noise in the holographic reconstruction.

2. The system of claim 1, wherein the laser diode chip comprises a plurality of ridges corresponding to the plurality of emitters.

3. The system of claim 1, wherein a dimension of an output port of one or more emitters of the plurality of emitters is less than 50 micrometers.

4. The system of claim 1, wherein a dimension of an output port of one or more emitters of the plurality of emitters is less than 20 micrometers.

5. The system of claim 1, wherein a distance between two adjacent emitters of the plurality of emitters is less than 500 micrometers.

6. The system of claim 1, wherein a distance between two adjacent emitters of the plurality of emitters is one of (i) less than 200 micrometers or (ii) less than 50 micrometers.

7. The system of claim 1, wherein the optic comprises a collimating lens.

8. The system of claim 1, wherein the overlap comprises at least 50% of a dimension of each beamlet.

9. The system of claim 1, wherein the hologram is arranged to distribute content of the holographic reconstruction of the picture by angle such that different angular ranges of light diffracted by the hologram correspond to different spatial portions of the picture.

10. The system of claim 1, further comprising a retina display, wherein the retina display comprises the holographic projector.

11. The system of claim 10, further comprising a head-up display, wherein the head-up display comprises the retina display.

12. A method of reducing noise in a retina display, wherein the method is performed by a holographic projector, and wherein the method comprises:
receiving, by an optic of the holographic projector, a plurality of beamlets, wherein individual beamlets of the plurality of beamlets are incoherent with each other such that they form different speckle patterns;
forming, by the optic, a continuous beam in which the plurality of beamlets at least partially overlap; and
illuminating a hologram of a picture with the continuous beam thereby forming a holographic reconstruction of the picture.

13. The method of claim 12, further comprising, prior to receiving, by the optic of the holographic projector, the plurality of beamlets, emitting, from a plurality of emitters of a laser diode chip of the holographic projector, the plurality of beamlets.

14. The method of claim 13, wherein emitting, from the plurality of emitters of the laser diode chip, the plurality of beamlets includes emitting, from a plurality of ridges of the laser diode chip, the plurality of beamlets.

15. The method of claim 13, wherein a dimension of an output port of one or more individual emitters of the plurality of emitters is less than 50 micrometers.

16. The method of claim 13, wherein a dimension of an output port of one or more individual emitters of the plurality of emitters is less than 20 micrometers.

17. The method of claim 13, wherein a distance between two adjacent emitters of the plurality of emitters is less than 500 micrometers.

18. The method of claim 13, wherein a distance between two adjacent emitters of the plurality of emitters is less than 200 micrometers.

19. The method of claim 12, wherein the optic comprises a collimating lens.

20. The method of claim 12, wherein the overlap comprises at least 50% of a dimension of each beamlet.

21. The method of claim 12, further comprising distributing, by the hologram, content of the holographic reconstruction of the picture by angle such that different angular ranges of light diffracted by the hologram correspond to different spatial portions of the picture.
